(19) United States
(12) Patent Application Publication
(10) Pub. No.: US 2021/0408358 A1
(43) Pub. Date: Dec. 30, 2021

(54) QUANTUM DEVICE AND METHOD OF MANUFACTURING THE SAME

(71) Applicant: NEC Corporation, Tokyo (JP)

(72) Inventors: Kenji Nanba, Tokyo (JP); Ayami Yamaguchi, Tokyo (JP); Akira Miyata, Tokyo (JP); Katsumi Kikuchi, Tokyo (JP); Suguru Watanabe, Tokyo (JP); Takanori Nishi, Tokyo (JP); Hideyuki Satou, Tokyo (JP)

(73) Assignee: NEC Corporation, Tokyo (JP)

(21) Appl. No.: 17/355,528

(22) Filed: Jun. 23, 2021

(30) Foreign Application Priority Data
Jun. 29, 2020 (JP) 2020-111953

(51) Int. Cl. H01L 39/24; G06N 10/00; H01L 27/18

(52) U.S. Cl. CPC H01L 39/2406; H01L 27/18; G06N 10/00

(57) ABSTRACT

A quantum device (100) includes: an interposer (112); a quantum chip (111); a first connection part (130) that is provided between the interposer (112) and the quantum chip (111) and electrically connects a wiring layer of the interposer (112) to a wiring layer of the quantum chip (111); a predetermined signal line (w1) arranged in the wiring layer of the quantum chip (111); first shield wires (ws1) arranged in the wiring layer of the quantum chip (111) along the predetermined signal line (w1); a second shield wire (ws2) arranged in the wiring layer of the interposer (112); and a second connection part (150) that is provided between the interposer (112) and the quantum chip (111) so as to contact the first shield wires (ws1) and the second shield wire (ws2).

### INCORPORATION BY REFERENCE

This application is based upon and claims the benefit of priority from Japanese patent application No. 2020-111953, filed on Jun. 29, 2020, the disclosure of which is incorporated herein in its entirety by reference.

### TECHNICAL FIELD

The present disclosure relates to a quantum device and a method of manufacturing the same.

### BACKGROUND ART

A quantum device formed of a superconducting material is mounted on a quantum computer device. This quantum device is placed in a cryogenic environment, whereby this quantum device is able to achieve operations that utilize superconducting phenomena. The cryogenic temperature indicates, for example, about 9 K when niobium (Nb) is used and about 1.2 K when aluminum (Al) is used.

A technique that relates to a quantum device is disclosed, for example, in Published Japanese Translation of PCT International Publication for Patent Application, No. 2019-537239. Published Japanese Translation of PCT International Publication for Patent Application, No. 2019-537239 discloses a structure in which a quantum dot device package and an interposer are coupled to each other by coupling components (including solder balls and the like).

According to the structure disclosed in Published Japanese Translation of PCT International Publication for Patent Application, No. 2019-537239, there is a problem that the quality of the structure is reduced since signals that propagate through signal lines formed in a wiring layer (quantum circuit) of a quantum dot device (quantum chip) are affected by interference due to exogenous noise such as electromagnetic waves.

### SUMMARY

An object of the present disclosure is to provide a quantum device and a method of manufacturing the same that solve the aforementioned problem.

According to one example embodiment, a quantum device includes: an interposer; a quantum chip; a first connection part that is provided between the interposer and the quantum chip and electrically connects a wiring layer of the interposer to a wiring layer of the quantum chip; a predetermined signal line arranged in the wiring layer of the quantum chip; a first shield wire arranged in the wiring layer of the quantum chip along the predetermined signal line; a second shield wire arranged in the wiring layer of the interposer; and a second connection part that is provided between the interposer and the quantum chip so as to contact the first shield wire and the second shield wire.

According to an example embodiment, a method of manufacturing a quantum device includes: arranging a predetermined signal line in a wiring layer of a quantum chip; arranging a first shield wire in the wiring layer of the quantum chip along the predetermined signal line; arranging a second shield wire in a wiring layer of an interposer; providing a first connection part on the interposer and providing a second connection part in such a way that the second connection part contacts the second shield wire; and arranging the quantum chip on the interposer in such a way that the second connection part contacts the first shield wire.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 is a schematic cross-sectional view of a quantum device according to a first example embodiment;

FIG. 2 is a schematic perspective view in which a second connection part of the quantum device shown in FIG. 1 and a surrounding area of the second connection part are enlarged;

FIG. 3 is a diagram for describing a method of manufacturing the second connection part of the quantum device shown in FIG. 1;

FIG. 4 is a diagram for describing a method of manufacturing the second connection part of the quantum device shown in FIG. 1;

FIG. 5 is a schematic cross-sectional view of a quantum device according to a second example embodiment;

FIG. 6 is a schematic cross-sectional view in which a second connection part of the quantum device shown in FIG. 5 and a surrounding area of the second connection part are enlarged;

FIG. 7 is a schematic cross-sectional view of a quantum device in a conceptual stage; and

FIG. 8 is a schematic perspective view in a which signal line w51 of the quantum device shown in FIG. 7 and a surrounding area of the signal line w51 are enlarged.

### EMBODIMENTS

Example embodiments of the present invention will be described below with reference to the accompanying drawings. Note that the drawings are in simplified form and the technical scope of the example embodiments should not be interpreted to be limited to the drawings. The same elements are denoted by the same reference numerals and a duplicate description is omitted.

In the following example embodiments, when necessary, the present invention is explained by using separate sections or separate example embodiments. However, those example embodiments are not unrelated with each other, unless otherwise specified. That is, they are related in such a manner that one example embodiment is a modified example, an application example, a detailed example, or a supplementary example of a part or the whole of another example embodiment. Further, in the following example embodiments, when the number of elements or the like (including numbers, values, quantities, ranges, and the like) is mentioned, the number is not limited to that specific number except for cases where the number is explicitly specified or the number is obviously limited to a specific number based on its principle. That is, a larger number or a smaller number than the specific number may also be used. For example, a plurality of quantum chips and a plurality of interposers may be formed.

Further, in the following example embodiments, the components (including operation steps and the like) are not necessarily indispensable except for cases where the component is explicitly specified or the component is obviously indispensable based on its principle. Similarly, in the following example embodiments, when a shape, a position relation, or the like of a component(s) or the like is mentioned, shapes or the like that are substantially similar to or resemble that shape are also included in that shape except for cases where it is explicitly specified or they are eliminated based on its principle. This is also true for the above-described number or the like (including numbers, values, quantities, ranges, and the like).

In the following, quantum computing refers to the field of utilizing quantum mechanical phenomena (quantum bits) to manipulate data. These quantum mechanical phenomena include superposition of a plurality of states (in which a quantum variable simultaneously exists in multiple different states) and entanglement (a state in which multiple quantum variables have related states irrespective of space or time). A quantum circuit that generates quantum bits is provided on a quantum chip.

### <Study in Advance by Inventors>

Prior to giving the description of a quantum device 100 according to a first example embodiment, contents studied in advance by the inventors will be described.

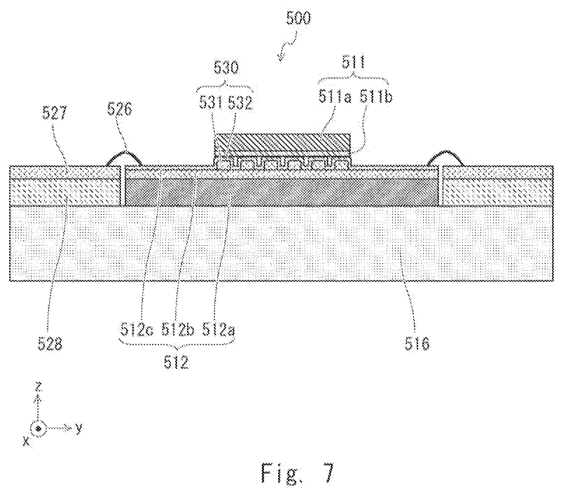

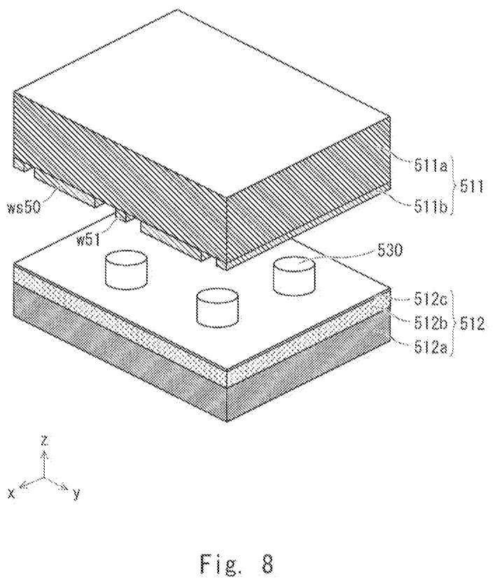

FIG. 7 is a schematic cross-sectional view of a quantum device 500 in a conceptual stage before reaching the first example embodiment. Further, FIG. 8 is a schematic perspective view in which a signal line (this may be either single or plural) w51 of the quantum device 500 and a surrounding area of the signal line w51 are enlarged. In FIG. 8, a quantum chip and an interposer are shown separately from each other. The quantum device 500 is mounted on a quantum computer device and placed in a cryogenic environment, whereby operations that utilize superconductive phenomena are achieved.

Specifically, the quantum device 500 includes a quantum chip 511, an interposer 512, a connection part 530, a sample table 516, a base substrate 528, and a bonding wire 526.

The interposer 512 and the base substrate 528 are arranged in proximity to each other on the main surface of the sample table 516. The sample table 516 includes a cooling function.

The interposer 512 includes an interposer substrate 512a, a wiring layer 512b, and a metal film 512c. The wiring layer 512b is formed on one main surface (the surface that is opposite to the surface that contacts the sample table 516) of the interposer substrate 512a (hereinafter it may also be simply referred to as an interposer 512), and the metal film 512c is further formed on the surface of the wiring layer 512b as a part of the wiring layer 512b.

The wiring layer 512b is formed of one of a superconducting material and a normal conducting material. The superconducting material is, for example, a metallic material such as niobium (Nb), niobium nitride (NbN), aluminum (Al), indium (In), lead (Pb), tin (Sn), rhenium (Re), palladium (Pd), titanium (Ti), titanium nitride (TiN), tantalum (Ta), and an alloy including any of them. The normal conducting material is, for example, a metallic material such as copper (Cu), silver (Ag), gold (Au), platinum (Pt), and an alloy including any of them. In this example, a case in which the wiring layer 512b is made of Cu, which is a normal conducting material, will be described.

Further, the metal film 512c is formed of a superconducting material. The superconducting material is, for example, a metallic material such as niobium (Nb), niobium nitride (NbN), aluminum (Al), indium (In), lead (Pb), tin (Sn), rhenium (Re), palladium (Pd), titanium (Ti), titanium nitride (TiN), tantalum (Ta), and an alloy including any of them. In this example, a case in which the metal film 512c is made of Nb will be described.

The quantum chip 511 includes a quantum chip body 511a and a wiring layer 511b. The wiring layer 511b is formed on one main surface of the quantum chip body 511a (hereinafter it may also be simply referred to as a quantum chip 511). The wiring layer 511b of the quantum chip 511 is formed of a superconducting material. In this example, a case in which the wiring layer 511b is made of Nb will be described.

The quantum chip 511 and the interposer 512 are arranged in such a way that the wiring layers thereof are opposed to each other.

The connection part 530 is provided between the quantum chip 511 and the interposer 512 and electrically connects the wiring layer 511b of the quantum chip 511 to the wiring layer 512b of the interposer 512. Accordingly, signals can be transferred between the quantum chip 511 and the interposer 512. Non-contact signal transfer may also be performed between the quantum chip 511 and the interposer 512.

Specifically, the connection part 530 includes a plurality of pillars 531 and a metal film 532. The plurality of pillars 531 are formed so as to be protruded from one main surface of the interposer 512. The metal film 532 is formed on the surface of the plurality of pillars 531. The metal film 532 is formed on the surface of the plurality of pillars 531 so as to be continuous with the metal film 512c formed on the surface of the wiring layer 512b of the interposer 512.

Note that the plurality of pillars 531 are made of one of a superconducting material and a normal conducting material. In this example, a case in which the plurality of pillars 531 are made of Cu, which is a normal conducting material, will be described. Further, the metal film 532 is formed of a superconducting material, just like the metal film 512c. In this example, a case in which the metal film 532 is made of Nb will be described.

The wiring layer 512b of the interposer 512 (including the metal film 512c) and a wiring layer 527 of the base substrate 528 are connected to each other via the bonding wire 526. Accordingly, signal lines (terminals) of the quantum chip 511 are externally drawn out via the interposer 512 and the bonding wire 526.

Further, heat in the quantum chip 511 is dissipated to the sample table 516 having a cooling function via the interposer 512. Accordingly, the quantum device 500 is maintained in a cryogenic state where superconducting phenomena can be utilized.

As shown in FIG. 8, the predetermined signal line (this may be either single or plural) w51 and shield wires ws50 are arranged in the wiring layer 511b of the quantum chip 511. The predetermined signal line w51, which is one or all of signal lines arranged in the wiring layer 511b, is, for example, a signal line that is susceptible to interference due to exogenous noise such as electromagnetic waves. Further, the shield wires ws50 serve a function of preventing interference due exogenous noise with respect to signals that propagate through the signal line w51.

Specifically, the shield wires ws50 are connected to the ground and the pair of shield wires ws50 is arranged along the signal line w51 so as to sandwich the signal line w51 (in the example shown in FIG. 8, x-axis direction). Accordingly, the shield wires ws50 are able to prevent interference due to exogenous noise with respect to signals that propagate through the signal line w51.

However, the exogenous noise can reach the signal line w51 via gaps in the connection part 530 (gaps formed between the plurality of pillars 531). Therefore, in the quantum device 500, the quality of the signals that propagate through the signal line w51 is still reduced because of interference due to exogenous noise such as electromagnetic waves.

In order to solve the above problem, a quantum device 100 according to a first example embodiment capable of improving the quality (quantum coherence etc.) by preventing interference in signals due to exogenous noise has been made.

### First Example Embodiment

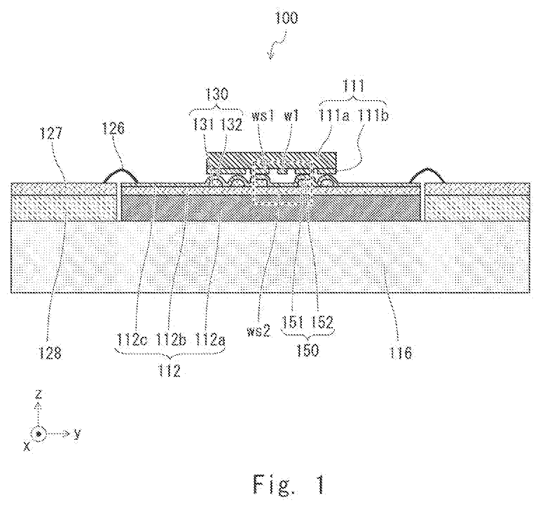

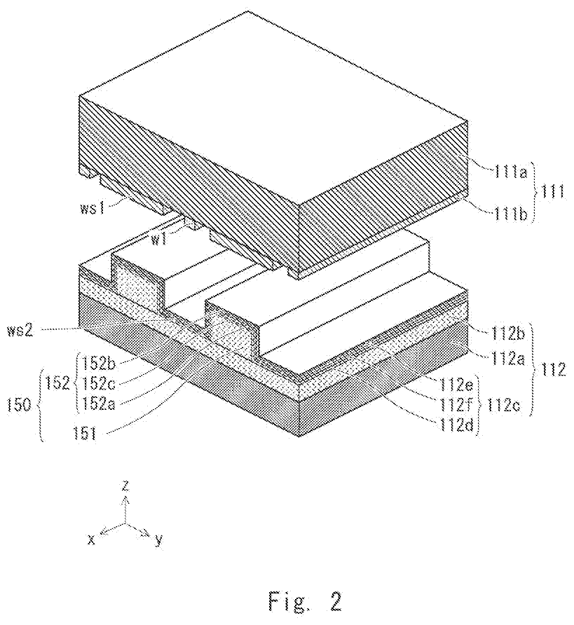

FIG. 1 is a schematic cross-sectional view of a quantum device 100 according to a first example embodiment. Further, FIG. 2 is a schematic perspective view in which a second connection part of the quantum device 100 and a surrounding area of the second connection part are enlarged. In FIG. 2, a quantum chip and an interposer are shown separately from each other. The quantum device 100 is mounted on a quantum computer device and is placed in a cryogenic environment, whereby operations that utilize superconducting phenomena are achieved.

Specifically, the quantum device 100 includes a quantum chip 111, an interposer 112, a first connection part 130, a second connection part 150, a sample table 116, a base substrate 128, and a bonding wire 126.

The interposer 112 and the base substrate 128 are arranged in proximity to each other on one main surface of the sample table 116. The sample table 116 includes a cooling function. Specifically, the sample table 116 is preferably made of copper (Cu), an alloy including copper, or aluminum (Al) in view of heat conduction. When the sample table 116 is made of aluminum, it may be insulated by alumite treatment.

The interposer 112 includes an interposer substrate 112a, a wiring layer 112b, and a metal film 112c. The wiring layer 112b is formed on one main surface (the surface that is opposite to the surface that contacts the sample table 116) of the interposer substrate 112a (hereinafter it may also be simply referred to as an interposer 112) and the metal film 112c is further formed on the surface of the wiring layer 112b as a part of the wiring layer 112b. The interposer 112 includes, for example, silicon (Si). The interposer 112 is not limited to the one that includes silicon as long as the quantum chip 111 can be mounted thereon, and the interposer 112 may include another electronic material such as sapphire, a compound semiconductor material (group IV, group III-V, group II-VI), glass, or ceramic. A surface of the interposer substrate 112a is preferably covered with a silicon oxide film (SiO2, TEOS film or the like).

The wiring layer 112b is formed of one of a superconducting material and a normal conducting material. The superconducting material is, for example, a metallic material such as niobium (Nb), niobium nitride (NbN), aluminum (Al), indium (In), lead (Pb), tin (Sn), rhenium (Re), palladium (Pd), titanium (Ti), titanium nitride (TiN), tantalum (Ta), and an alloy including any of them. The normal conducting material is, for example, a metallic material such as copper (Cu), silver (Ag), gold (Au), platinum (Pt), and an alloy including any of them. In this example, a case in which the wiring layer 112b is made of Cu, which is a normal conducting material, will be described.

Further, the metal film 112c includes a single-layer structure or a multi-layer structure and at least one layer thereof is formed of a superconducting material. The superconducting material is, for example, a metallic material such as niobium (Nb), niobium nitride (NbN), aluminum (Al), indium (In), lead (Pb), tin (Sn), rhenium (Re), palladium (Pd), titanium (Ti), titanium nitride (TiN), tantalum (Ta), and an alloy including any of them. In this example, a case in which the metal film 112c includes a three-layer structure, the bottom layer 112d that contacts the wiring layer 112b is made of Nb, the top layer 112e is made of In, and the intermediate layer 112f between them is made of Ti or TiN will be described. The intermediate layer 112f made of Ti or TiN is provided in order to improve adhesiveness between the Nb layer 112d and the In layer 112e.

The quantum chip 111 includes a quantum chip body 111a and a wiring layer 111b. The wiring layer 111b is formed on one main surface of the quantum chip body 111a (hereinafter it may also be simply referred to as a quantum chip 111). The quantum chip 111 includes, for example, silicon (Si). The quantum chip 111 is not limited to the one that includes silicon as long as this quantum chip 111 is able to form quantum bits, and may include another electronic material such as sapphire or a compound semiconductor material (group IV, group III-V, group II-VI). Further, while the quantum chip 111 is preferably a monocrystal quantum chip, it may instead be a polycrystal or amorphous quantum chip. Further, the wiring layer 111b of the quantum chip 111 is formed of a superconducting material. In this example, a case in which the wiring layer 111b is made of Nb will be described.

The quantum chip 111 and the interposer 112 are arranged in such a way that the wiring layers 111b and 112b thereof are opposed to each other.

The first connection part 130 is provided between the quantum chip 111 and the interposer 112 and electrically connects the wiring layer 111b of the quantum chip 111 to the wiring layer 112b of the interposer 112. Accordingly, signals can be transferred between the quantum chip 111 and the interposer 112. Non-contact signal transfer may also be performed between the quantum chip 111 and the interposer 112.

Specifically, the first connection part 130 includes a plurality of pillars 131 and a metal film 132. The plurality of pillars 131 are formed in such a way that they are protruded from one main surface of the interposer 112. The metal film 132 is formed on a surface of the plurality of pillars 131. The metal film 132 is formed on a surface of the plurality of pillars 131 in such a way that the metal film 132 is continuous with the metal film 112c formed on the surface of the wiring layer 112b of the interposer 112.

Note that the plurality of pillars 131 are formed of one of a superconducting material and a normal conducting material. In order to enhance the cooling performance, for example, they are preferably formed of a normal conducting material. In this example, a case in which the plurality of pillars 131 are made of Cu, which is a normal conducting material, will be described. Further, at least a part of the metal film 132 is formed of a superconducting material, just like the metal film 112c. That is, in this example, a case in which the metal film 132 includes a three-layer structure, the bottom layer is made of Nb, the top layer that contacts the wiring layer 111b of the quantum chip 111 is made of In, the intermediate layer provided therebetween is made of Ti or TiN will be described.

The wiring layer 112b of the interposer 112 (including the metal film 112c) and a wiring layer 127 of the base substrate 128 are connected to each other by the bonding wire 126. Accordingly, signal lines (terminals) of the quantum chip 111 are externally drawn out via the interposer 112 and the bonding wire 126.

Further, heat in the quantum chip 111 is dissipated to the sample table 116 that has a cooling function via the interposer 112. Accordingly, the quantum device 100 is maintained in a cryogenic state where superconducting phenomena can be utilized.

As shown in FIG. 2, a predetermined signal line (this may be either single or plural) w1 and shield wires (first shield wires) ws1 are arranged in the wiring layer 111b of the quantum chip 111. The predetermined signal line w1, which is one or all of signal lines arranged in the wiring layer 111b, is, for example, a signal line that is susceptible to interference due to exogenous noise such as electromagnetic waves. The signal line that is susceptible to interference due to exogenous noise is, for example, a bending part of the signal line, an end part (the part where symmetry is lost) of the signal line that is symmetrical when it is viewed from above or the like. Further, the shield wires ws1 serve a function of preventing interference due exogenous noise with respect to signals that propagate through the signal line w1.

Specifically, the shield wires ws1 are arranged in pairs in the wiring layer 111b of the quantum chip 111 along the signal line w1 (in the example shown in FIG. 2, along the x-axis direction) so as to sandwich the signal line w1. Note that the shield wires ws1 are connected to the ground. Accordingly, the shield wires ws1 are able to prevent interference due to exogenous noise from the horizontal direction (any direction on the xy-plane).

Further, the second connection part 150 and at least one shield wire (second shield wire) (it may be either single or plural) ws2 are provided in the quantum device 100.

Specifically, the pair of the second connection parts 150 are provided in the wiring layer 112b of the interposer 112 along the respective shield wires ws1 provided in pairs (in the example shown in FIG. 2, along the x-axis direction) in such a way that the pair of the second connection parts 150 contact the respective shield wires ws1. In other words, the pair of the second connection parts 150 are provided in the same layer as the first connection part 130 along the respective shield wires ws1 provided in pairs in such a way that the pair of the second connection parts 150 contact the respective shield wires ws1. Further, the shield wire ws2 is arranged between the pair of the second connection parts 150 in the wiring layer 112b of the interposer 112 in such a way that the shield wire ws2 contacts the pair of the second connection part 150. Both the second connection parts 150 and the shield wire ws2 are connected to the ground. That is, the shield wires ws1, the shield wire ws2, and the second connection parts 150 include a structure that is close to a coaxial structure that surrounds the outer periphery of the signal line w1. Accordingly, the shield wires ws1, the shield wire ws2, and the second connection parts 150 are able to prevent interference due to not only exogenous noise from the horizontal direction but also exogenous noise including components in the vertical direction (that is, prevent interference due to exogenous noise from any direction). As a result, the quantum device 100 is able to ensure the signal characteristics at high frequencies and improve noise resistance. That is, the quantum device 100 is able to improve the quality (quantum coherence etc.)

In this example, the second connection part 150 is made of a metallic material the same as that of the first connection part 130. Specifically, the second connection part 150 includes a projection part 151, and a metal film 152 formed on a surface of the projection part 151. The metal film 152 is formed on a surface of the projection part 151 in such a way that it is continuous with the metal film 112c formed on a surface of the wiring layer 112b of the interposer 112. The metal film 152 does not necessarily cover the entire surface of the projection part 151 and may be provided to cover at least a part of the surface of the projection part 151 (e.g., one of the surfaces of the projection part 151 which is on the side of the signal line w1 arranged in the wiring layer 111b of the quantum chip 111). Further, in this example, the shield wire ws2 is formed of the wiring layer 112b of the interposer 112 and the metal film 112c formed on its surface. However, the shield wire ws2 may be formed only of the metallic material (in this example, Cu) of the wiring layer 112b without using the metal film 112c.

In the second connection part 150, the projection part 151 is formed of one of a superconducting material and a normal conducting material, and the metal film 152 is formed of a superconducting material. In this example, the projection part 151 is made of Cu, just like the pillars 131 of the first connection part 130, the metal film 152 includes a three-layer structure, just like the metal film 132 of the first connection part 130, the bottom layer 152a is made of Nb, the top layer 152b is made of In, and the intermediate layer 152c provided therebetween is made of Ti or TiN. Since the top layer 152b that contacts the shield wires ws1 is made of a metallic material having a high ductility like In, adhesiveness between the shield wires ws1 and the second connection part 150 is improved (the size of the bonding area can be efficiently increased following the irregularities of the bonded surface). Accordingly, it is possible to prevent interference due to exogenous noise more efficiently.

Next, a method of manufacturing the quantum device 100 will be partly described. First, the predetermined signal line w1 is formed in the wiring layer 111b of the quantum chip 111 and the shield wires ws1 that shield the signal line w1 are formed. Further, the wiring layer 112b is formed on one main surface of the interposer 112, and then the plurality of pillars 131 are formed in such a way that they are protruded from one main surface of the interposer 112. After that, along with the timing when the metal film 112c is formed on the surface of the wiring layer 112b, the metal film 132 is formed on the surface of the plurality of pillars 131. The first connection part 130 is thus formed. Further, the second connection part 150 is formed through a manufacturing process similar to the process of manufacturing the first connection part 130. The wiring layer 112b between the pair of the second connection parts 150 and the metal film 112c formed on its surface are used as the shield wire ws2. After that, the quantum chip 111 is arranged on one main surface of the interposer 112 in such a way that the wiring layer 111b of the quantum chip 111 contacts the first connection part 130 and the shield wires ws1 contact the second connection part 150. The quantum device 100 is formed through the above process.

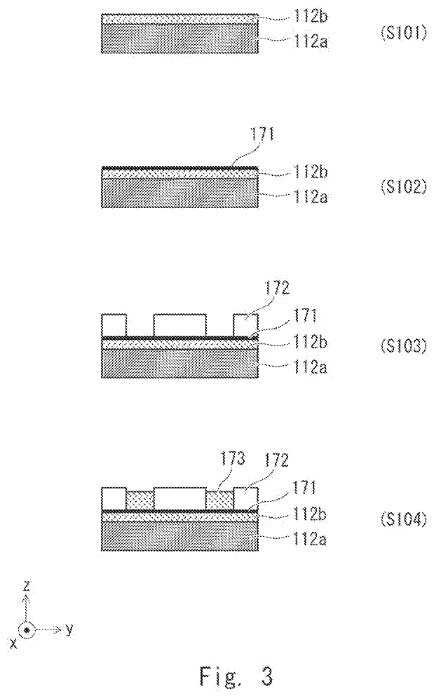

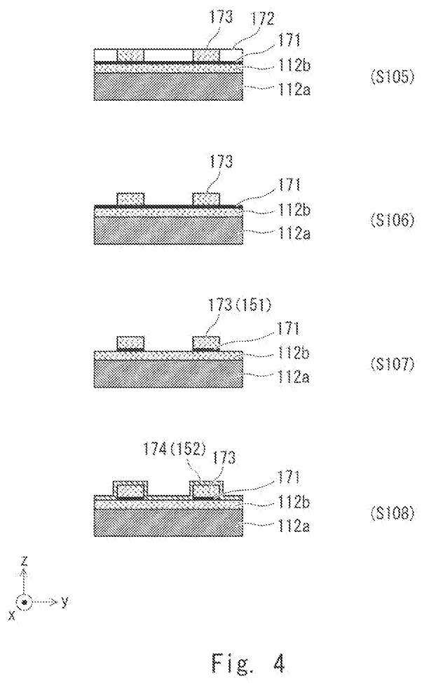

Note that the second connection part 150 is manufactured, for example, by the procedure shown in FIGS. 3 and 4.

First, the interposer 112 is prepared (Step S101). After that, Ti and a Cu 171 are formed in order on one main surface of the interposer 112 (surface of the wiring layer 112b) by sputtering (Step S102). After that, a resist 172 having a mask pattern of the second connection part 150 is formed on its surface (Step S103), and a copper plated part 173 (it corresponds to the projection part 151) is formed in the opening part of the resist 172 by an electroplating method (Step S104). After that, the upper surface of the copper plated part 173 is flattened by machining (Step S105), and the resist 172 is removed (Step S106). After that, Ti and the Cu 171 other than the plated part are removed by etching (Step S107). After that, Nb, Ti, and an In 174 (corresponding to the metal film 152) are formed in order on the surface of the copper plated part 173 by sputtering (Step S108). The second connection part 150 is formed through the above process.

As described above, in the quantum device 100 according to this example embodiment, the predetermined signal line w1 arranged in the wiring layer 111b of the quantum chip 111 is shielded not only by the shield wires ws1 arranged in the wiring layer 111b of the quantum chip 111 but also by the second connection part 150 and the shield wire ws2 provided in the wiring layer 112b of the interposer 112. Accordingly, the quantum device 100 is able to efficiently prevent interference due to exogenous noise with respect to signals that propagate through the signal line w1. As a result, the quantum device 100 is able to ensure the signal characteristics at high frequencies and improve noise resistance. That is, the quantum device 100 is able to improve the quality (quantum coherence etc.)

While the case in which the wiring layer 112b of the interposer 112 is formed of a normal conducting material and at least a part of the metal film 112c formed on its surface is formed of a superconducting material has been described in this example embodiment, this is merely one example. The wiring layer 112b of the interposer 112 may be formed of a superconducting material such as Nb. In this case, the metal film 112c may not be formed on the surface of the wiring layer 112b. Further, in this case, for example, the wiring layer 112b of the interposer 112, the metal film 132 formed in the first connection part 130, and the metal film 152 formed in the second connection part 150 are formed in such a way that they are continuous with one another (integrally formed).

Further, regarding the shape of the shield wires ws1, as long as the distance between the predetermined signal line w1 arranged in the wiring layer of the quantum chip and the surface of the shield wire ws1 that is closer to the signal line w1 is a predetermined distance, the shape of the surface of the shield wire ws1 that is opposite to the surface of the shield wire ws1 that is closer to the signal line w1 does not need to be parallel to the surface of the shield wire ws1 that is closer to the signal line w1.

### Second Example Embodiment

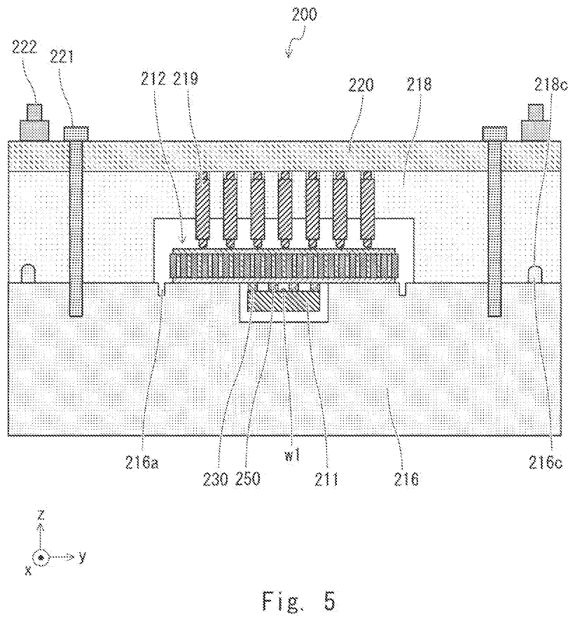

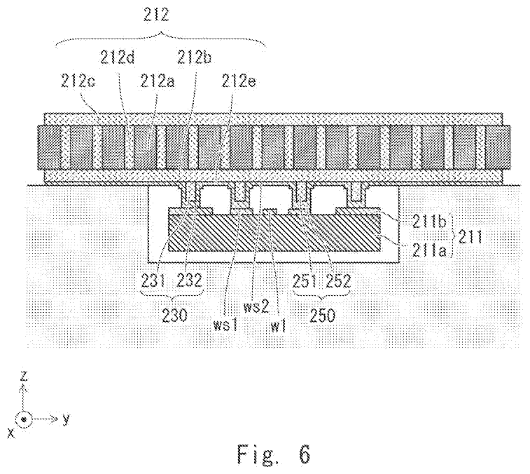

FIG. 5 is a schematic cross-sectional view of a quantum device 200 according to a second example embodiment. FIG. 6 is a schematic cross-sectional view in which a second connection part of the quantum device 200 and a surrounding area of the second connection part are enlarged. The quantum device 200 includes a device structure that is different from that of the quantum device 100.

Specifically, the quantum device 200 includes a quantum chip 211, an interposer 212, first connection parts 230, second connection parts 250, a sample table 216, a probe head 218, probe pins 219, a probe card 220, fixing screws 221, and plugs 222.

The sample table 216 includes a recessed part at the center of its main surface (upper surface) and the quantum chip 211 is arranged inside each recessed part with gaps therebetween. The quantum chip 211 may be formed in such a way that it can fit within the recessed part. Further, alignment holes 216a used when the quantum chip 211 is arranged inside the recessed part of the sample table 216 are provided on the main surface of the sample table 216. Accordingly, the quantum chip 211 can be accurately arranged inside the recessed part of the sample table 216. Further, alignment pins 216c that correspond to holes 218c provided in the probe head 218 are provided on the main surface of the sample table 216. Accordingly, the probe head 218 can be accurately arranged in the sample table 216. Note that the sample table 216 is preferably made of copper (Cu), an alloy including copper, or aluminum (Al) in view of heat conduction. When the sample table 216 is made of aluminum, it may be insulated by alumite treatment.

The interposer 212 includes an interposer substrate 212a, a wiring layer 212b, a wiring layer 212c, and a Through Via (TV) 212d. The wiring layer 212b is formed on one main surface (the surface where the quantum chip 211 is provided) of the interposer substrate 212a (hereinafter it may also be simply referred to as an interposer 212) and a metal film 212e is further formed as a part of the wiring layer 212b on the surface of the wiring layer 212b. The wiring layer 212c is formed on the other main surface of the interposer substrate 212a. The wiring layers 212b and 212c are electrically connected to each other via the TV 212d formed inside the interposer substrate 212a. The interposer 212 includes, for example, silicon (Si). Note that the interposer 212 is not limited to the one that includes silicon as long as the quantum chip 211 can be mounted thereon and may include another electronic material such as sapphire, a compound semiconductor material (group IV, group III-V, group II-VI), glass, or ceramic. The surface of the interposer substrate 212a is preferably covered with a silicon oxide film (SiO2, TEOS film or the like). Further, when silicon is used, a Through Silicon Via (TSV) is used as the TV 212d.

The wiring layers 212b and 212c, and the TV 212d are each formed of one of a superconducting material and a normal conducting material. The superconducting material is, for example, a metallic material such as niobium (Nb), niobium nitride (NbN), aluminum (Al), indium (In), lead (Pb), tin (Sn), rhenium (Re), palladium (Pd), titanium (Ti), titanium nitride (TiN), tantalum (Ta), and an alloy including any of them. The normal conducting material is, for example, a metallic material such as copper (Cu), silver (Ag), gold (Au), platinum (Pt), and an alloy including any of them. In this example, a case in which the wiring layers 212b and 212c, and the TV 212d are all made of Cu, which is a normal conducting material, will be described.

Further, the metal film 212e includes a single-layer structure or a multi-layer structure and at least one layer is formed of a superconducting material. The superconducting material is, for example, a metallic material such as niobium (Nb), niobium nitride (NbN), aluminum (Al), indium (In), lead (Pb), tin (Sn), rhenium (Re), palladium (Pd), titanium (Ti), titanium nitride (TiN), tantalum (Ta), and an alloy including any of them. In this example, a case in which the metal film 212e includes a three-layer structure, the bottom layer 212f that contacts the wiring layer 112b is made of Nb, the top layer 212g is made of In, and the intermediate layer 212h provided therebetween is made of Ti or TiN will be described (none of them is shown). Note that the intermediate layer 212h made of Ti or TiN is provided in order to improve adhesiveness between the Nb layer 212f and the In layer 212g.

The quantum chip 211 includes a quantum chip body 211a and a wiring layer 211b. The wiring layer 211b is formed on one main surface of the quantum chip body 211a (hereinafter it may also be simply referred to as a quantum chip 211). The quantum chip 211 includes, for example, silicon (Si). The quantum chip 211 is not limited to the one that includes silicon as long as the quantum chip 211 is able to form quantum bits, and may include another electronic material such as sapphire or a compound semiconductor material (group IV, group III-V, group II-VI). Further, while the quantum chip 211 is preferably a monocrystal quantum chip, it may instead be a polycrystal or amorphous quantum chip. Further, the wiring layer 211b of the quantum chip 211 is formed of a superconducting material. In this example, a case in which the wiring layer 211b is made of Nb will be described.

The quantum chip 211 and the interposer 212 are arranged in such a way that the wiring layers 211b and 212b thereof are opposed to each other.

The first connection part 230 is provided between the quantum chip 211 and the interposer 212 and electrically connects the wiring layer 211b of the quantum chip 211 to the wiring layer 212b of the interposer 212. Accordingly, signals can be transferred between the quantum chip 211 and the interposer 212. Non-contact signal transfer may also be performed between the quantum chip 211 and the interposer 212.

Specifically, the first connection part 230 includes a plurality of pillars 231 and a metal film 232. The plurality of pillars 231 are formed (arranged) in such a way that they are protruded from one main surface of the interposer 212 (the surface where the quantum chip 211 is provided) to an area where the quantum chip 211 is mounted. The metal film 232 is formed (arranged) on the surface of the plurality of pillars 231 in such a way that the metal film 232 is continuous with the metal film 212e formed on a surface of the wiring layer 212b of the interposer 212.

The plurality of pillars 231 are formed of one of a superconducting material and a normal conducting material. In order to enhance the cooling performance, for example, they are preferably formed of a normal conducting material. In this example, a case in which the plurality of pillars 231 are made of Cu, which is a normal conducting material, will be described. Further, at least a part of the metal film 232 is formed of a superconducting material, just like the metal film 212e. That is, in this example, a case in which the metal film 232 includes a three-layer structure, the bottom layer 232a is made of Nb, the top layer 232b that contacts the wiring layer 211b of the quantum chip 211 is made of In, and the intermediate layer 232c provided therebetween is made of Ti or TiN will be described (none of them is shown).

The probe head 218 is arranged on the sample table 216 and the probe card 220 is further arranged on the probe head 218. The probe head 218 is provided with the holes 218c and the alignment pins 216c that correspond to the holes 218c are provided in the sample table 216. Accordingly, the probe head 218 can be accurately arranged in the sample table 216. Further, they are fixed to the sample table 216 by fixing screws 221. Therefore, desired positions of the wiring layer 212c of the interposer 212 can be accurately touched with the probe pins 219. Further, the plugs 222 are arranged on the probe card 220.

The probe head 218 has a recessed part on its bottom surface and the interposer 212 is arranged in the recessed part thereof. That is, the quantum chip 211 and the interposer 212 are arranged in a space region formed of the recessed part of the probe head 218 and the recessed part of the sample table 216. This space region is preferably in a vacuum state. Accordingly, the heat insulation property is improved, whereby heat transfer from the interposer 212 to the quantum chip 211 can be, for example, prevented.

The plurality of probe pins 219 are provided between the interposer 212 and the probe card 220 and electrically connect the wiring layer 212c formed on the other surface of the interposer 212 (the surface that is opposite to the surface where the quantum chip 211 is provided) to the probe card 220. Accordingly, signal lines (terminals) of the quantum chip 211 are externally drawn out via the interposer 212, the probe pins 219, the probe card 220, and the plugs 222.

Further, heat in the quantum chip 211 is dissipated to the sample table 216 having a cooling function via the interposer 212. Accordingly, the quantum device 200 is maintained in a cryogenic state where superconducting phenomena can be utilized.

As shown in FIGS. 5 and 6, a predetermined signal line w1 and shield wires (first shield wires) ws1 are arranged in the wiring layer 211b of the quantum chip 211. The predetermined signal line w1, which is one or all of signal lines arranged in the wiring layer 211b, is, for example, a signal line that is susceptible to interference due to exogenous noise such as electromagnetic waves. The signal line that is susceptible to interference due to exogenous noise is, for example, a bending part of the signal line, an end part (the part where symmetry is lost) of the signal line that is symmetrical when it is viewed from above. Further, the shield wires ws1 serve a function of preventing interference due to exogenous noise with respect to signals that propagate through the signal line w1.

Specifically, the shield wires ws1 are arranged in pairs in the wiring layer 211b of the quantum chip 211 along the signal line w1 (along the x-axis direction in the examples shown in FIGS. 5 and 6) so as to sandwich the signal line w1. The shield wires ws1 are connected to the ground. Accordingly, the shield wires ws1 are able to prevent interference due to exogenous noise from the horizontal direction (any direction on the xy-plane).

Further, the quantum device 200 is provided with the second connection parts 250 and shield wire (second shield wire) ws2.

Specifically, the pair of the second connection parts 250 are provided in the wiring layer 212b of the interposer 212 along the respective shield wires ws1 provided in pairs (in the examples shown in FIGS. 5 and 6, along the x-axis direction) in such a way that the pair of the second connection parts 250 contact the respective shield wires ws1. In other words, the pair of the second connection parts 250 are provided in the same layer as the first connection part 230 along the respective shield wires ws1 provided in pairs in such a way that the pair of the second connection parts 250 contact the respective shield wires ws1. Further, the shield wire ws2 is arranged between the pair of the second connection parts 250 in the wiring layer 212b of the interposer 212 in such a way that the shield wire ws2 contacts the pair of the second connection part 250. Both the second connection parts 250 and the shield wire ws2 are connected to the ground. That is, the shield wires ws1, the shield wire ws2, and the second connection parts 250 include a structure that is close to a coaxial structure that surrounds the outer periphery of the signal line w1. Accordingly, the shield wires ws1, the shield wire ws2, and the second connection parts 250 are able to prevent interference due to not only exogenous noise from the horizontal direction but also exogenous noise including components in the vertical direction (that is, prevent interference due to exogenous noise from any direction). As a result, the quantum device 200 is able to ensure the signal characteristics at high frequencies and improve noise resistance. That is, the quantum device 200 is able to improve the quality (quantum coherence etc.)

In this example, the second connection part 250 is formed of a metallic material that is the same as that of the first connection part 230. Specifically, the second connection part 250 includes a projection part 251 and a metal film 252 formed on a surface of the projection part 251. The metal film 252 is formed on a surface of the projection part 251 so as to be continuous with the metal film 212e formed on a surface of the wiring layer 212b of the interposer 212. Note that the metal film 252 is not limited to being applied to a case in which it covers the entire surface of the projection part 251 and may be provided so as to cover at least a part of the surface of the projection part 251 (e.g., of the surfaces of the projection part 251, the surface on the side of the signal line w1 arranged in the wiring layer 211b of the quantum chip 211). Further, in this example, the shield wire ws2 is formed of the wiring layer 212b of the interposer 212 and the metal film 212e formed on its surface. However, the shield wire ws2 may be made only of a metallic material (in this example, Cu) of the wiring layer 212b, without using the metal film 212e.

In the second connection part 250, the projection part 251 is formed of one of a superconducting material and a normal conducting material and the metal film 252 is formed of a superconducting material. In this example, the projection part 251 is made of Cu, just like the pillars 231 of the first connection part 230. Further, the metal film 252 includes a three-layer structure, just like the metal film 232 of the first connection part 230, the bottom layer 252a is made of Nb, the top layer 252b is made of In, the intermediate layer 252c thereof is made of Ti or TiN. Since the top layer 252b that contacts the shield wires ws1 is formed of a metallic material having a high ductility like In, adhesiveness between the shield wires ws1 and the second connection part 250 is improved (the size of the bonding area can be efficiently increased following the irregularities of the bonded surface). Accordingly, it is possible to prevent interference due to exogenous noise more efficiently.

Next, a method of manufacturing the quantum device 200 will be partly described. First, the predetermined signal line w1 is formed in the wiring layer 211b of the quantum chip 211 and the shield wires ws1 that shield the signal line w1 are formed. Further, the wiring layer 212b is formed on one main surface of the interposer 212 and then the plurality of pillars 231 are formed so that they are protruded from one main surface of the interposer 212. After that, along with the timing when the metal film 212e is formed on the surface of the wiring layer 212b, the metal film 232 is formed on the surface of the plurality of pillars 231. The first connection part 230 is thereby formed. Further, after a manufacturing process similar to the process of manufacturing the first connection part 230, the second connection part 250 is formed. The wiring layer 212b provided between the pair of the second connection parts 250 and the metal film 212e formed on its surface are used as the shield wire ws2. After that, the quantum chip 211 is arranged on one main surface of the interposer 212 in such a way that the wiring layer 211b of the quantum chip 211 contacts the first connection part 230 and that the shield wires ws1 contact the second connection part 250. The quantum device 200 is provided through the above process.

As described above, in the quantum device 200 according to this example embodiment, the predetermined signal line w1 arranged in the wiring layer 211b of the quantum chip 211 is shielded not only by the shield wires ws1 arranged in the wiring layer 211b of the quantum chip 211 but also by the second connection part 250 and the shield wire ws2 provided in the wiring layer 212b of the interposer 212. Accordingly, the quantum device 200 is able to efficiently prevent interference due to exogenous noise with respect to signals that propagate through the signal line w1. As a result, the quantum device 200 is able to ensure the signal characteristics at high frequencies and improve noise resistance. That is, the quantum device 200 is able to improve the quality (quantum coherence etc.)

While the case in which the wiring layer 212b of the interposer 212 is formed of a normal conducting material and at least a part of the metal film 212e formed on its surface is formed of a superconducting material has been described in this example embodiment, this is merely one example. The wiring layer 212b of the interposer 212 may be formed of a superconducting material such as Nb. In this case, the metal film 212e may not be formed on the surface of the wiring layer 212b. Further, in this case, for example, the wiring layer 212b of the interposer 212, the metal film 232 formed in the first connection part 230, and the metal film 252 formed in the second connection part 250 are formed (integrally formed) so as to be continuous with each other.

While the example embodiments of the present disclosure have been described in detail with reference to the drawings, the specific configurations are not limited to the aforementioned ones and various design changes may be made without departing from the spirit of the present disclosure.

While the case in which the wiring layer of the quantum chip is made of Nb and the metal films of the first connection part and the second connection part include a three-layer structure made of Nb, Ti (or TiN), and In has been described in the aforementioned first and second embodiments, this is merely one example. It is sufficient that the metal films of the first connection part and the second connection part include a single-layer structure or a multi-layer structure and at least one layer be formed of a superconducting material.

Specifically, for example, the wiring layer of the quantum chip may be made of Nb and the metal films of the first connection part and the second connection part may include a single-layer structure formed of a superconducting material such as Nb. The same is applied also to the metal film formed on the surface of the wiring layer of the interposer.

Alternatively, the wiring layer of the quantum chip may be made of Al and a layer made of Ti or TiN may be further provided in parts where the first connection part and the second connection part are arranged. Further, the metal films of the first connection part and the second connection part may include a three-layer structure, which may be made of Al, Ti (or TiN), In, or an alloy including the same in order from the bottom layer to the top layer. Note that Sn, Pb, or an alloy including any of them may be used in place of In or an alloy including the same. The Ti layer or the TiN layer is provided so as to prevent alloying of Al and In. The same is applied also to the metal film formed on the surface of the wiring layer of the interposer.

Alternatively, the wiring layer of the quantum chip may be made of Ta, the metal films of the first connection part and the second connection part may include a two-layer structure, the bottom layer may be made of Ta, and the top layer may be made of In, Sn, Pb, or an alloy including any of them. The same is applied also to the metal film formed on the surface of the wiring layer of the interposer.

According to the example embodiment, it is possible to provide a quantum device and a method of manufacturing the same capable of improving the quality (quantum coherence etc.)

The first and second embodiments can be combined as desirable by one of ordinary skill in the art.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

The whole or part of the exemplary embodiments disclosed above can be described as, but not limited to, the following supplementary notes.

### (Supplementary Note 1)

A quantum device comprising:

an interposer;

a quantum chip;

a first connection part that is provided between the interposer and the quantum chip and electrically connects a wiring layer of the interposer to a wiring layer of the quantum chip;

a predetermined signal line arranged in the wiring layer of the quantum chip;

a first shield wire arranged in the wiring layer of the quantum chip along the predetermined signal line;

a second shield wire arranged in the wiring layer of the interposer; and

a second connection part that is provided between the interposer and the quantum chip so as to contact the first shield wire and the second shield wire.

### (Supplementary Note 2)

The quantum device according to Supplementary Note 1, wherein the first shield wire, the second shield wire, and the second connection part are all connected to the ground.

### (Supplementary Note 3)

The quantum device according to Supplementary Note 1 or 2, wherein

the first shield wires are arranged in pairs along the predetermined signal line in such a way that the first shield wires sandwich the predetermined signal line,

the second connection parts are provided in pairs along the respective first shield wires provided in pairs, and

the second shield wire is arranged between the pair of the second connection parts.

### (Supplementary Note 4)

The quantum device according to any one of Supplementary Notes 1 to 3, wherein the second connection part is formed using a material the same as that of the first connection part.

### (Supplementary Note 5)

The quantum device according to any one of Supplementary Notes 1 to 4, wherein

the second connection part comprises:

a projection part that is provided on a main surface of the interposer and is formed of a normal conducting material; and

a metal film that is provided to cover at least a part of a surface of the projection part, at least a part of the metal film being formed of a superconducting material.

### (Supplementary Note 6)

The quantum device according to Supplementary Note 5, wherein the metal film is provided in such a way that it is continuous from a wiring layer arranged on a main surface of the interposer or a surface of the wiring layer.

### (Supplementary Note 7)

The quantum device according to Supplementary Note 5 or 6, wherein the metal film includes a multi-layer structure, at least one layer of the metal film being formed of a superconducting material.

### (Supplementary Note 8)

The quantum device according to any one of Supplementary Notes 5 to 7, wherein the metal film includes a multi-layer structure, the top layer thereof being formed of a metallic material having a ductility higher than those of the other layers.

### (Supplementary Note 9)

The quantum device according to any one of Supplementary Notes 5 to 8, wherein the predetermined signal line is a bending part or an end part of signal lines that are symmetrical when they are viewed from above among the signal lines arranged in the wiring layer of the quantum chip.

### (Supplementary Note 10)

A method of manufacturing a quantum device, the method comprising:

arranging a predetermined signal line in a wiring layer of a quantum chip;

arranging a first shield wire in the wiring layer of the quantum chip along the predetermined signal line;

arranging a second shield wire in a wiring layer of an interposer;

providing a first connection part on the interposer and providing a second connection part in such a way that the second connection part contacts the second shield wire; and

arranging the quantum chip on the interposer in such a way that the second connection part contacts the first shield wire.

What is claimed is:

1. A quantum device comprising:
an interposer;
a quantum chip;
a first connection part that is provided between the interposer and the quantum chip and electrically connects a wiring layer of the interposer to a wiring layer of the quantum chip;
a predetermined signal line arranged in the wiring layer of the quantum chip;
a first shield wire arranged in the wiring layer of the quantum chip along the predetermined signal line;
a second shield wire arranged in the wiring layer of the interposer; and
a second connection part that is provided between the interposer and the quantum chip so as to contact the first shield wire and the second shield wire.

2. The quantum device according to claim 1, wherein the first shield wire, the second shield wire, and the second connection part are all connected to the ground.

3. The quantum device according to claim 1, wherein
the first shield wires are arranged in pairs along the predetermined signal line in such a way that the first shield wires sandwich the predetermined signal line,
the second connection parts are provided in pairs along the respective first shield wires provided in pairs, and
the second shield wire is arranged between the pair of the second connection parts.

4. The quantum device according to claim 1, wherein the second connection part is formed using a material the same as that of the first connection part.

5. The quantum device according to claim 1, wherein
the second connection part comprises:
a projection part that is provided on a main surface of the interposer and is formed of a normal conducting material; and
a metal film that is provided to cover at least a part of a surface of the projection part, at least a part of the metal film being formed of a superconducting material.

6. The quantum device according to claim 5, wherein the metal film is provided in such a way that it is continuous from a wiring layer arranged on a main surface of the interposer or a surface of the wiring layer.

7. The quantum device according to claim 5, wherein the metal film includes a multi-layer structure, at least one layer of the metal film being formed of a superconducting material.

8. The quantum device according to claim 5, wherein the metal film includes a multi-layer structure, the top layer thereof being formed of a metallic material having a ductility higher than those of the other layers.

9. The quantum device according to claim 5, wherein the predetermined signal line is a bending part or an end part of signal lines that are symmetrical when they are viewed from above among the signal lines arranged in the wiring layer of the quantum chip.

10. A method of manufacturing a quantum device, the method comprising:
arranging a predetermined signal line in a wiring layer of a quantum chip;
arranging a first shield wire in the wiring layer of the quantum chip along the predetermined signal line;
arranging a second shield wire in a wiring layer of an interposer;
providing a first connection part on the interposer and providing a second connection part in such a way that the second connection part contacts the second shield wire; and
arranging the quantum chip on the interposer in such a way that the second connection part contacts the first shield wire.
